(19) United States
(12) Patent Application Publication
(10) Pub. No.: US 2026/0221185 A1
(43) Pub. Date: Jul. 30, 2026

(54) RESISTIVE RANDOM-ACCESS MEMORY (RERAM) CONFIGURED FOR OVERCOMING THE AFFECTS OF READ DISTURB

(71) Applicant: Weebit Nano Ltd., Hod Hasharon (IL)

(72) Inventors: Gabriel MOLAS, Fontanil (FR); Giuseppe PICCOLBONI, Grenoble (FR)

(73) Assignee: Weebit Nano Ltd., Hod Hasharon (IL)

(21) Appl. No.: 19/147,475

(22) PCT Filed: Jan. 13, 2023
(86) PCT No.: PCT/IB2023/000008

§ 371 Date: Jul. 11, 2025

(51) Int. Cl. G11C 13/00

(52) U.S. Cl. CPC G11C 13/0033; G11C 13/0061; G11C 13/0069

(57) ABSTRACT

Resistive random-access memories (ReRAMs) suffer from a read disturb phenomenon that results from the fact that the read and programming operations use the same voltage polarity, though at different voltages. After a number of reads, which may be small or large depending on the characteristic of each cell, outlier cells distinctly switch after a much small number of reads than other cells. Accordingly, a process comprising SET or RESET operation of the ReRAM cells, is followed by a CLEAN operation. The CLEAN operation involves application of a cleaning voltage that is greater than the read voltage and lesser than the programming voltage. Subsequently, a READ operation is performed to identify those ReRAM cells that have switched from their expected state. In an embodiment a reprogramming operation takes place to fix the resistive filament of the ReRAM cells identified to suffer from the read disturb.

### CROSS-REFERENCE TO RELATED APPLICATIONS

This application is a national stage application of International Patent Application No. PCT/IB2023/000008, filed on Jan. 13, 2023, now pending, the contents of which are hereby incorporated by reference.

### TECHNICAL FIELD

The present disclosure generally relates to resistive random-access memory (ReRAM) cells, and more particularly to read disturb or ReRAM cells.

### BACKGROUND

Typical resistive random-access memory (ReRAM) devices suffer from a phenomenon known as read disturb. While a small read voltage may not disturb a current state of a ReRAM cell, the distribution of cells is such that these occurrences cannot be ignored. A disturbance is when a cell that is supposed to be at a low-resistance state (LRS), typically a logical ‘1’, is affected by one or more read cycles and switches to a high-resistance state (HRS), typically a logical ‘0’. Similarly, the reverse may be true, a cell that is supposed to be at HRS is affected by one or more read cycles and switches to LRS. This is possible as the reading and writing of a ReRAM cell is performed at the same voltage polarity, albeit at different voltage amplitude. Therefore, after a sufficient number of reading cycles the memory may unintentionally switch. This may be limiting on applications that rely on a large number of read operations, for example, artificial intelligence (AI) circuits, inference mode, and others.

FIG. 1 shows a diagram 100 that explains the relationship between V_{read}, i.e., the voltage used for reading a ReRAM cell, and V_{prog}, i.e., the voltage used to program the ReRAM cell. FIG. 1 therefore shows an example diagram of reading and programming voltages of ReRAM cells having distribution between fast and slow cells versus the switch time showing the time to disturb. The horizontal axis 110 of the diagram 100 shows the voltage being applied. The vertical axis 120 of the diagram 100 shows the time to disturb, or switch time, typically presented as a logarithmic scale. It therefore should be understood that ReRAM cells present a time voltage dilemma as the switching time is an exponential function of the applied voltage.

As shown in FIG. 1 cells may have different characteristics, a fast memory cell, depicted by the graph FAST 140, will suffer from a low disturb time, i.e., the cell will be disturbed at a shorter period of time when compared to a slow memory cell. On the other hand, a slow memory cell, depicted by the graph SLOW 130, will be slow to read. That being shown on a logarithmic scale means that there may be one or more order of magnitude difference between the read performances of the fast and slow memory cells, both of which may be present on the same ReRAM memory array.

FIG. 2A shows plot 200A with graphs 230A, 240A, 250A, 260A and 270A for application of a plurality of read voltages Va, 0.9V, 0.8V, 0.7V, 0.6V and 0.5V respectively, on an array of ReRAMs with respect of the horizontal axis denoting disturb time 220A, shown on a logarithmic scale) and the vertical axis denoting percent of failed cells 210A (shown between 0% and 100%). The graph is created for every Va, by gradually increasing the read time while measuring the number of switched cells. Consider graph 230A that shows a nominal Gaussian distribution, however, there are outliers in the times up to about 10⁻⁶, which represents roughly 25% of the cells switching at a short period of time, at V_{d}=0.9V. For comparison, a theoretical curve 235A was added to denote the case where no outliers exist. At a lower Va, for example 0.8V graph 240A has a lower percent of cells that switch initially, roughly 15%, and disturb time increase to about 10⁻⁴. As is seen, the lower the Va, see graphs 250A, 260A and 270A, the lesser the percent of cells switching. This presents a problem as it means that a fast memory will suffer from low disturb time while a resilient memory will be slow.

FIG. 2B is a graph 200B of distribution of outlier ReRAM cells and nominal ReRAM cells of a ReRAM array. The horizontal axis 210B depicts the number of reads to switch a cell, i.e., how many reads to the cell will cause it to switch from its initial state, ‘1’ or ‘0’ to the opposite state, ‘0’ or ‘1’ respectively. The vertical axis 220B show the probably to switch at a given V_{read}. Graph 230B shows the probability of switching of outlier cells, while graph 240B shows the probability of switching of the nominal cells. As can be seen there is a gap 250B that exists between the number of reads that typify outlier cells and the nominal cells. This means that the switching probability is bimodal.

FIG. 2C is a graph 200C that shows distribution of the SLOW 230C ReRAM cells and the FAST 240C ReRAM cells with respect to read voltage versus time to disturb. The bimodal distribution shown in FIG. 2B is now provided on graph 200C for both the SLOW distribution 235C and FAST distribution 245C. They are represented where the horizontal axis 210 is the read voltage and the vertical axis 220C shows the time to disturb, i.e., the time by which a cell will switch from a current state to its other possible state.

It would be advantageous to provide a solution that will overcome the read disturb of ReRAM cells.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “some embodiments” or “certain embodiments” may be used herein to refer to a single embodiment or multiple embodiments of the disclosure.

Certain embodiments disclosed herein include a method for initializing a resistive random-access memory (ReRAM) against read disturb, the method comprising: programming all ReRAM cells of the ReRAM to an initial state at a first programing voltage; performing a clean operation on all the ReRAM cells, wherein the clean voltage is at a lower absolute value than the first programming voltage, and wherein the clean operation is performed for a predetermined period of time that is longer than the switching time of a first group of ReRAM cells that are read disturbed after a first predetermined number of reads and a second group of ReRAM cells that are read disturbed after a second predetermined number of reads, wherein the first predetermined number of reads is smaller than the second predetermined number of reads; and, performing a read operation on all the ReRAM cells to determine which of the ReRAM cells have been affected by a read disturb, wherein read is performed at an absolute voltage that is lower than the absolute voltage value of the clean operation.

Certain embodiments disclosed herein also include a control logic of a ReRAM configured to address read disturb of ReRAM cells of the ReRAM, the control logic comprising: a processing circuitry; an input/output (IO) interface communicatively connected to the processing circuit, wherein the IO interface comprises at least control signals of the ReRAM; and, a memory communicatively connected to the processing circuitry, the memory containing therein instructions that when executed by the processing circuitry configure the control logic to: program all ReRAM cells of the ReRAM to an initial state at a first programing voltage; perform a clean operation on all the ReRAM cells, wherein the clean voltage is at a lower absolute value than the first programming voltage, and wherein the clean operation is performed for a predetermined period of time that is longer than the switching time of a first group of ReRAM cells that are read disturbed after a first predetermined number of reads and a second group of ReRAM cells that are read disturbed after a second predetermined number of reads, wherein the first predetermined number of reads is smaller than the second predetermined number of reads; and, perform a read operation on all the ReRAM cells to determine which of the ReRAM cells have been affected by a read disturb, wherein read is performed at an absolute voltage that is lower than the absolute voltage value of the clean operation.

Certain embodiments disclosed herein further include a ReRAM configured to address read disturb of ReRAM cells of the ReRAM, the control logic comprising: an array of ReRAM cells; a word-line decoder communicatively connected to the array of ReRAM cells using at least one word-line; a bit-line/select-line decoder communicatively connected to the array of ReRAM cells using at least one bit-line and at least one select line; a control logic communicatively connected to the word-line decoder and to the bit-line/select-line decoder, the control logic comprising: a processing circuitry; an input/output (IO) interface communicatively connected to the processing circuit, wherein the IO interface comprises at least control signals of the ReRAM; and a memory communicatively connected to the processing circuitry, the memory containing therein instructions that when executed by the processing circuitry configure the control logic to: program all ReRAM cells of the ReRAM to an initial state at a first programing voltage; perform a clean operation on all the ReRAM cells, wherein the clean voltage is at a lower absolute value than the first programming voltage, and wherein the clean operation is performed for a predetermined period of time that is longer than the switching time of a first group of ReRAM cells that are read disturbed after a first predetermined number of reads and a second group of ReRAM cells that are read disturbed after a second predetermined number of reads, wherein the first predetermined number of reads is smaller than the second predetermined number of reads; and, perform a read operation on all the ReRAM cells to determine which of the ReRAM cells have been affected by a read disturb, wherein read is performed at an absolute voltage that is lower than the absolute voltage value of the clean operation.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 is a diagram of reading and programming voltages of ReRAM cells having distribution between fast and slow cells versus the switch time showing the time to disturb.

FIG. 2A shows graphs for application of a plurality of read voltages Vd on an array of ReRAMs with respect of disturb time and the percent of failed cells.

FIG. 2B is a graph of distribution of outlier ReRAM cells and nominal ReRAM cells of a ReRAM array.

FIG. 2C is a graph that shows distribution of SLOW and FAST ReRAM cells with respect to read voltage versus time to disturb.

FIG. 3 is a graph depicting the use of a clean voltage to identify outlier cells of a ReRAM according to an embodiment.

FIG. 4 is a time diagram of operations of initializing ReRAM cells comprising a SET, CLEAN and READ operations according to an embodiment.

FIG. 5 is a time diagram of operations of initializing ReRAM cells comprising a RESET, CLEAN and READ operations according to an embodiment.

FIG. 6 is a ReRAM having a control logic to control initialization processes according to an embodiment.

FIG. 7 is a control logic of the ReRAM configured to perform the initialization processes according to an embodiment.

FIG. 8 is a flowchart of the initializing of ReRAM cells comprising a SET, CLEAN and READ operations according to an embodiment.

FIG. 9 is a flowchart of the initializing of ReRAM cells comprising a RESET, CLEAN and READ operations according to an embodiment.

FIG. 10 is a graph for determination of a desired CLEAN voltage according to an embodiment.

### DETAILED DESCRIPTION

It is important to note that the embodiments disclosed herein are only examples of the many advantageous uses of the innovative teachings herein. In general, statements made in the specification of the present application do not necessarily limit any of the various claims. Moreover, some statements may apply to some inventive features but not to others. In general, unless otherwise indicated, singular elements may be in plural and vice versa with no loss of generality. In the drawings, like numerals refer to like parts through several views.

Resistive random-access memories (ReRAMs) suffer from a read disturb phenomenon that results from the fact that the read and programming operations use the same voltage polarity, though at different voltages. After a number of reads, which may be small or large depending on the characteristic of each cell, outlier cells distinctly switch after a much small number of reads than other cells. Accordingly, a process comprising SET or RESET operation of the ReRAM cells, is followed by a CLEAN operation. The CLEAN operation involves application of a cleaning voltage that is greater than the read voltage and lesser than the programming voltage. Subsequently, a READ operation is performed to identify those ReRAM cells that have switched from their expected state. In an embodiment a reprogramming operation takes place to fix the resistive filament of the ReRAM cells identified to suffer from the read disturb.

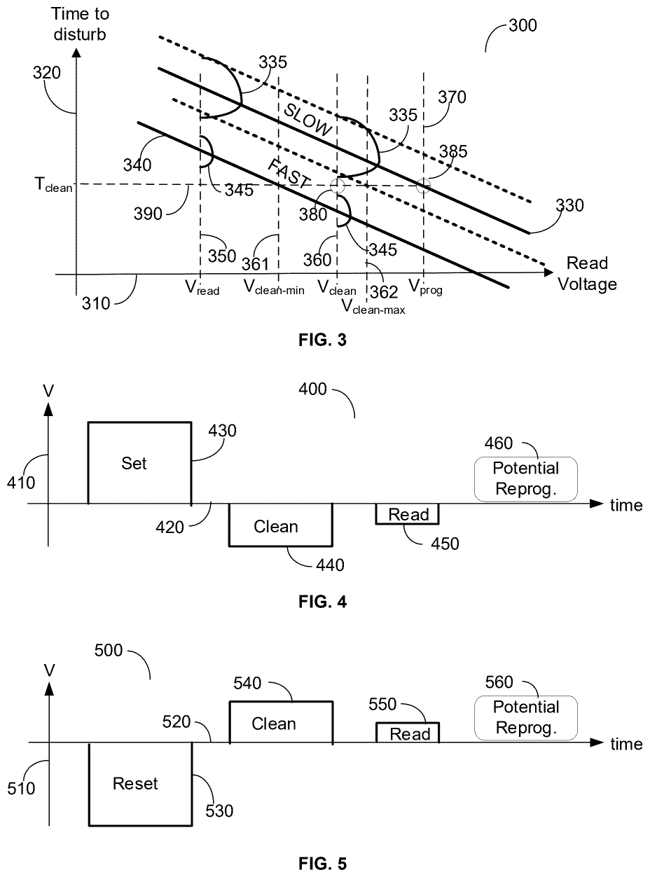

FIG. 3 is an example graph 300 depicting the use of a clean voltage to identify outlier cells of a ReRAM according to an embodiment. Graph 300 comprises a horizontal axis 310 that shows the read voltage and a vertical axis 320 that shows the time to disturb on a logarithmic scale. ReRAM cells may have a SLOW characteristic depicted by graph 330 or a FAST characteristic depicted by graph 340. There is a distribution of both the SLOW ReRAM cells shown by graph 335 and the FAST ReRAM cells shown by graph 340. The distribution occurs through the entire length of each of the graphs 330 and 340. The programming voltage used for the ReRAM cells may be set at V_{prog} 370. According to an embodiment the crossing-point 385 of that voltage-point with the SLOW graph 370 determines the clean time T_{clean} 390. The in-turn allows for the determination of the V_{clean} 360 voltage where its cross-point 380 with T_{clean} 390 is fixed at the gap between the distribution graphs 335 and 345. The voltage V_{clean} 360 is higher, in absolute terms, than the voltage V_{read} 350, and lower in absolute terms than the voltage V_{prog} 370. V_{clean} 360 can be established between V_{clean-min} 361, that meets the distribution edge of the FAST graph 340, and V_{clean}-max 362, that meets the edge of the SLOW distribution 330.

FIG. 4 is an example time diagram 400 of operations for initializing ReRAM cells comprising a SET 430, CLEAN 440 and READ 450 operations according to an embodiment. The vertical axis 410 is the applied voltage, not necessarily to scale. The horizontal axis 420 is time, not necessarily to scale. The cells of a ReRAM memory are exercised according to an embodiment by first performing a SET operation 430, i.e., bringing the filaments of the cells of the ReRAM to their SET, or low resistance state (LRS) of the cells ReRAM. The read voltage for this case is a voltage that is smaller than 0V. A CLEAN operation 440, that involves the application of a V_{clean} 360 voltage at a value described herein, is applied. V_{clean} 360 is greater, in absolute value, than the read voltage V_{read} 350. The application of V_{clean} 360 for a period T_{clean} 390 exercises those ReRAM cells which are currently prone to read disturb. This is because the time used for T_{clean} is greater than the time need to read disturb the FAST ReRAM cells but not long enough to read disturb the SLOW ReRAM cells. A following READ operation 450 is performed to establish which of the ReRAM cells have suffered from read disturb and therefore not found in their expected SET value, or LRS. In an embodiment reprogramming 460 may take place to SET those ReRAM cells that have suffered from read disturb. This initialization process of the ReRAM array ensures an improved performance of the entire array with less likelihood of early read disturb.

FIG. 5 is an example time diagram 500 of operations for initializing ReRAM cells comprising a RESET 530, CLEAN 540 and READ 550 operations according to an embodiment. The vertical axis 510 is the applied voltage, not necessarily to scale. The horizontal axis 520 is time, not necessarily to scale. The cells of a ReRAM memory are exercised according to an embodiment by first performing a RESET operation 530, i.e., bringing the filaments of the cells of the ReRAM to their RESET, or high resistance state (HRS) of the cells ReRAM. The read voltage for this case is a voltage that is higher than 0V. A CLEAN operation 540, that involves the application of a V_{clean} 360 voltage at a value described herein, is applied. V_{clean} 360 is greater, in absolute value, than the read voltage V_{read} 350. The application of V_{clean} 360 for a period T_{clean} 390 exercises those ReRAM cells which are currently prone to read disturb. This is because the time used for T_{clean} 390 is greater than the time need to read disturb the FAST ReRAM cells but not long enough to read disturb the SLOW ReRAM cells. A following READ operation 550 is performed to establish which of the ReRAM cells have suffered from read disturb and therefore not found in their expected RESET value, or HRS. In an embodiment reprogramming 560 may take place to RESET those ReRAM cells that have suffered from read disturb. This initialization process of the ReRAM array ensures an improved performance of the entire array with less likelihood of early read disturb. One of ordinary skill in the art would readily realize that the RESET flow described for FIG. 5 uses the opposite voltage scheme than the one described for FIG. 4.

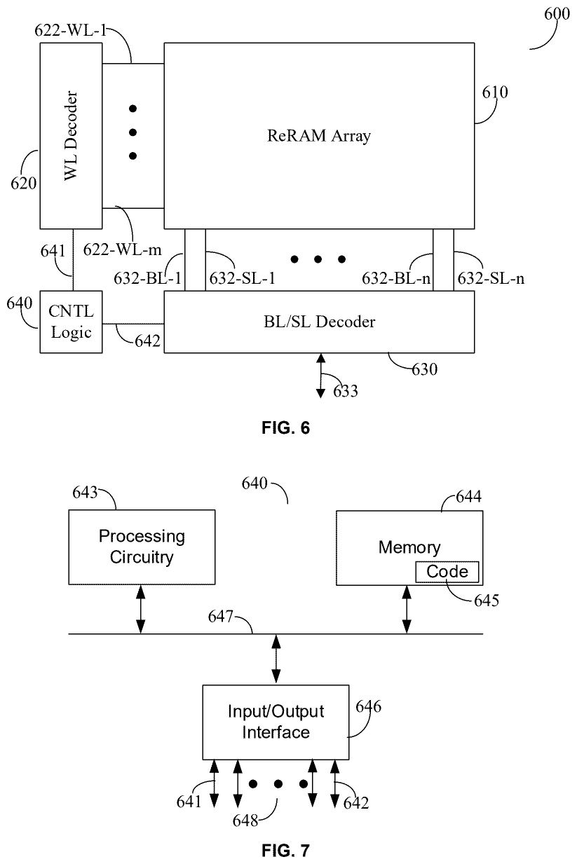

FIG. 6 is an example ReRAM 600 having a control logic 640 to control initialization processes according to an embodiment. The ReRAM 600 comprises a ReRAM array 610, which is comprised from ReRAM cells (not shown) that are connected in rows and columns in one or more ways known in the art. In order to set, reset, program, clean or read, any of the ReRAM cells, word-line (WL) decoder 620 and bit-line (BL)/select-line (SL) decoder 630 are used under the control of the control logic 640. The control logic 640 is communicatively connected to the WL decoder 620 by interface 641. The WL decoder 620 is communicatively connected to the ReRAM array 610 by a plurality of word-lines 622-WL-m, where ‘m’ is an integer equal to or greater than ‘1’. The control logic 640 is further communicatively connected to the BL/SL decoder 630 by interface 642. The SL/BL decoder 630 is communicatively connected to the ReRAM array 610 by bit-lines 632-BL-n, and by select-lines 632-SL-n, where ‘n’ is an integer equal to or greater than ‘1’. Read and write operations of the ReRAM 600 is performed using a data interface 633 provided from the BL/SL decoder 630. The control logic 640 is configured to provide the necessary control signals and, in some embodiments, the necessary voltages, to perform the operations described herein.

FIG. 7 is an example control logic 640 of the ReRAM 600 configured to perform the initialization processes according to an embodiment. A processing circuitry 643 is communicatively connected to a memory 644 by, for example but not by way of limitation, a bus 647. The memory 644 may contain therein a portion dedicated for code 645, stored in the memory 644. When the code contained in code memory 645 is executed by the processing circuitry 643, the ReRAM 600 is configured to perform as described herein. Memory 644 may comprise volatile memory such as, but not by way of limitation, random access memory (RAM). Memory 644 may comprise non-volatile memory (NVM), such as, but not limited to, Flash memory, read only memory (ROM) and other types of NVMs. The memory may comprise any combination of volatile and non-volatile memories. To the bus 647 an input/output (IO) interface 646 is communicatively connected. The IO interface 646 provides for the control of the WL decoder 620 using interface 641 and the BL/SL decoder 630 using interface 642. Additionally, interface 648 may provide, for example but without limitation, for external communication, to receive various command signals to the ReRAM 600 for control of its operation as well as provide output signals as may be required.

The processing circuitry 643 may be realized as one or more hardware logic components and circuits. For example, and without limitation, illustrative types of hardware logic components that can be used include field-programmable gate arrays (FPGAs), application-specific integrated circuits (ASICs), Application-specific standard products (ASSPs), system-on-a-chip systems (SOCs), general-purpose microprocessors, microcontrollers, digital signal processors (DSPs), and the like, whether general purpose or specialized processors, or any other hardware logic components that can perform calculations or other manipulations of information. It should be further understood that while a control circuit 640 is shown to operate using a processing circuitry 643 with instructions stored in a memory 644, other embodiments of the control circuit 640 are also possible and are specifically included as embodiments of the invention. For example, without limitation, the control circuit 640 may comprise combinations of digital and analog circuits (not shown) that provide at least at the interface 641 and 642 control signals that configure the ReRAM 600 for the initialization process to achieve the same overall results. The control circuit 640 is configured to perform the ReRAM initialization operations describe in greater detail herein.

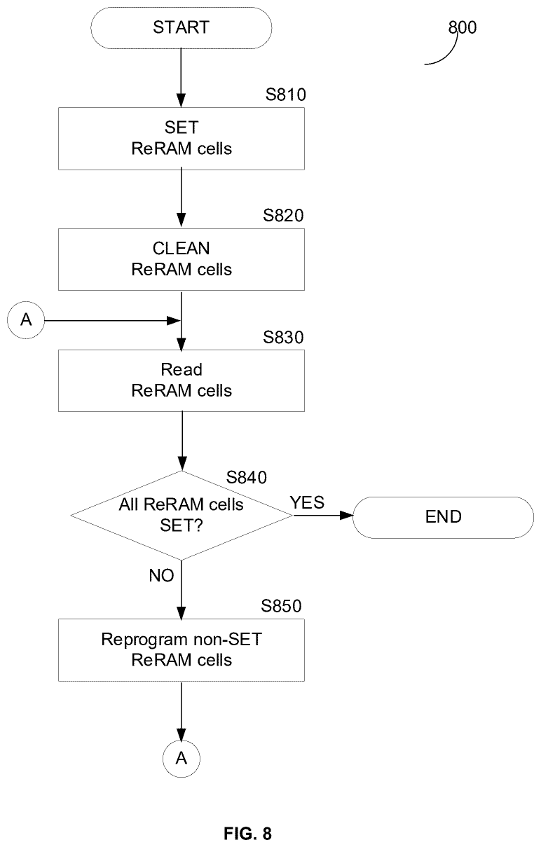

FIG. 8 is an example flowchart 800 of the initializing of ReRAM cells comprising a SET, CLEAN and READ operations according to an embodiment. At S810 a SET operation of the ReRAM cells is performed, for example, on the ReRAM cells of ReRAM 600. In the SET operation all ReRAM cells in a ReRAM array, for example ReRAM array 610, are expected to be a LRS which is associated with a logical ‘1’.

At S820 a CLEAN operation is performed. The CLEAN operation is performed by applying to the ReRAM array cells a CLEAN voltage V_{clean} 350, that is selected within a predetermined voltage range as explained herein. It should be noted that for proper operation according to the invention it is necessary to keep |V_{prog}|>|V_{clean}|>|V_{read}|. These voltages may be supplied by the control circuit 640, the WL decoder 620, the BL/SL decoder 630. The CLEAN operation is performed for a predetermined period of time T_{clean} 390, which is a period of time by which all those of the ReRAM cells that switch early due to read disturb have already switched, but most others have not (see also FIG. 3 and associated text, among others).

At S830 the ReRAM cells are read to check which cells have been impacted from the CLEAN operation of S820.

At S840 it is checked whether all of the ReRAM cells of the ReRAM array are at SET and if not, execution continues with S850; otherwise, execution terminates. In an embodiment the check is not if all ReRAM cells are at SET but rather a threshold number of ReRAM cells, for example but not by way of limitation, 99.99%, or no more than 0.01% failure, is used to determine when It is OK to terminate the process. In an embodiment the ReRAM cells determined not to be operable are mapped out of the valid cells for use.

At S850 reprogramming of the ReRAM cells that have shown to have failed, i.e., are at a RESET, or HRS, instead of SET, or LRS, as expected, takes place. Thereafter execution continues with S830. In an embodiment once reprogramming takes place, execution terminates. In yet another embodiment reprogramming is performed at V_{prog} 370 however, it is possible to also reprogram these cells at a voltage that is higher than V_{prog} 370, i.e., |V_{reprog}|>|V_{prog}| without departing from the scope of the invention.

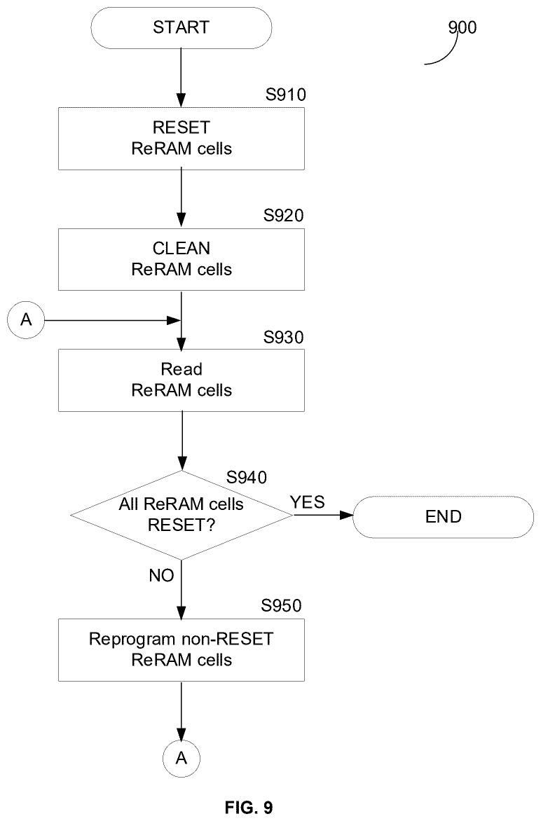

FIG. 9 is an example flowchart 900 of the initializing of ReRAM cells comprising a RESET, CLEAN and READ operations according to an embodiment. At S910 a RESET operation of the ReRAM cells is performed, for example, on the ReRAM cells of ReRAM 600. In the RESET operation all ReRAM cells in a ReRAM array, for example ReRAM array 610, are expected to be a HRS which is associated with a logical ‘0’.

At S920 a CLEAN operation is performed. The CLEAN operation is performed by applying to the ReRAM array cells a CLEAN voltage V_{clean} 360, that is selected with a predetermined voltage range as explained herein. It should be noted that for proper operation according to the invention it is necessary to keep |V_{prog}|>|V_{clean}|>|V_{read}|. These voltages may be supplied by the control circuit 640, the WL decoder 620, the BL/SL decoder 630. The CLEAN operation is performed for a predetermined period of time T_{clean}, which is a period of time by which all those of the ReRAM cells that switch early due to read disturb have already switched, but most others have not (see also FIG. 3 and associated text, among others).

At S930 the ReRAM cells are read to check which cells have been impacted from the CLEAN operation of S920.

At S840 it is checked whether all of the ReRAM cells of the ReRAM array are at RESET and if not, execution continues with S950; otherwise, execution terminates. In an embodiment the check is not if all ReRAM cells are at SET but rather a threshold number of ReRAM cells, for example but not by way of limitation, 99.99%, or no more than 0.01% failure, is used to determine when It is OK to terminate the process. In an embodiment the ReRAM cells determined not to be operable are mapped out of the valid cells for use.

At S950 reprogramming of the ReRAM cells that have shown to have failed, i.e., are at a SET, or LRS, instead of RESET, or HRS, as expected, takes place. Thereafter execution continues with S930. In an embodiment once reprogramming takes place, execution terminates. In yet another embodiment reprogramming is performed at V_{prog} 370 however, it is possible to also reprogram these cells at a voltage that is higher than V_{prog} 370, i.e., |V_{reprog}|>|V_{prog}| without departing from the scope of the invention. A higher |I_{reprog}|>|I_{prog}| may also be used. Such higher values of I_{reporg} and V_{reprog} can strengthen those “weak” ReRAM cells that exhibited read disturb.

In an embodiment only one polarity is used to read, either positive or negative. If V_{read}>0, then RESET cells are affected by the read operation. If V_{read}<0, then SET cells are affected by the read operation. Thus V_{read}>0 (resp. V_{read}<0) does not affect LRS while V_{read}<0 does not affect HRS. In such a case where both SET and RESET are used there is only one CLEAN operation, either after SET or after RESET, depending on the polarity of V_{read} used.

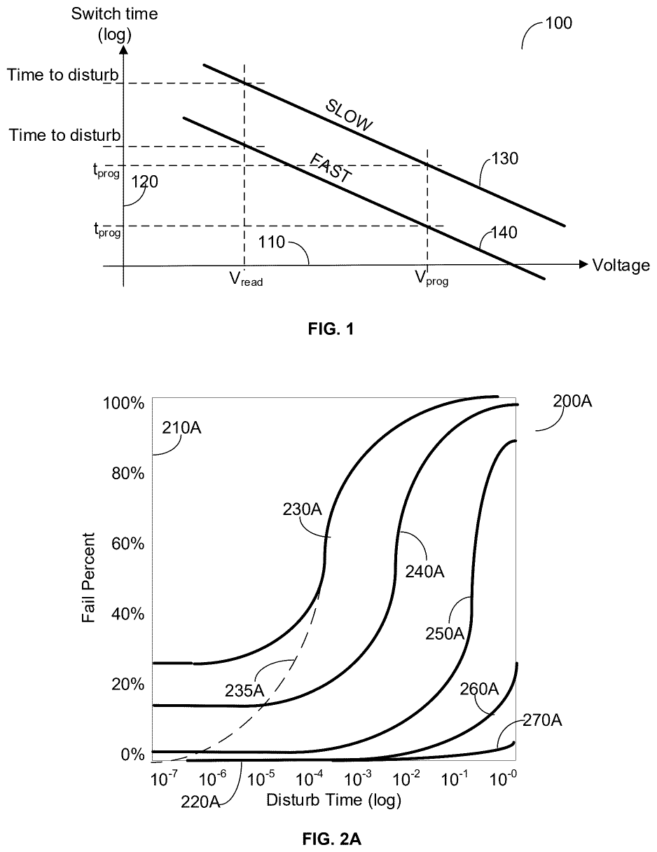

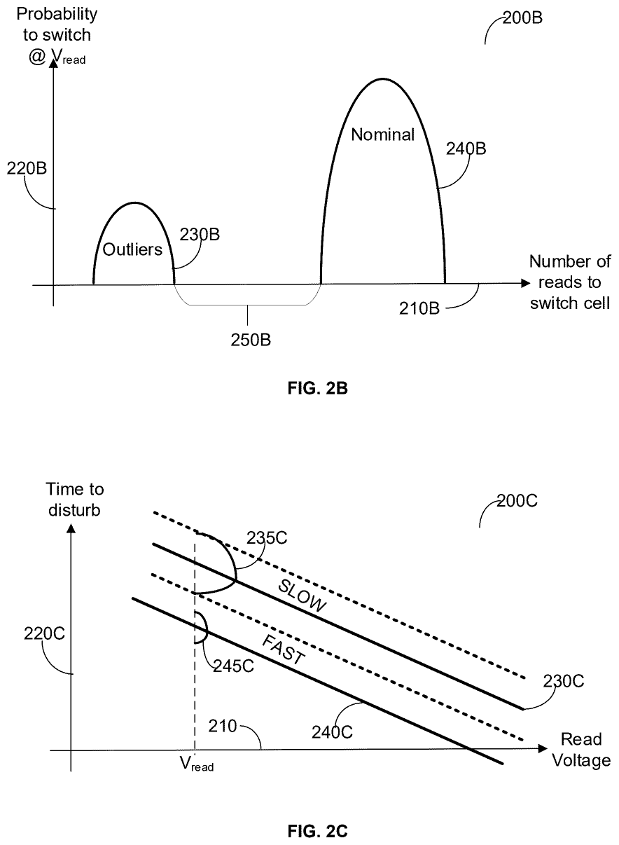

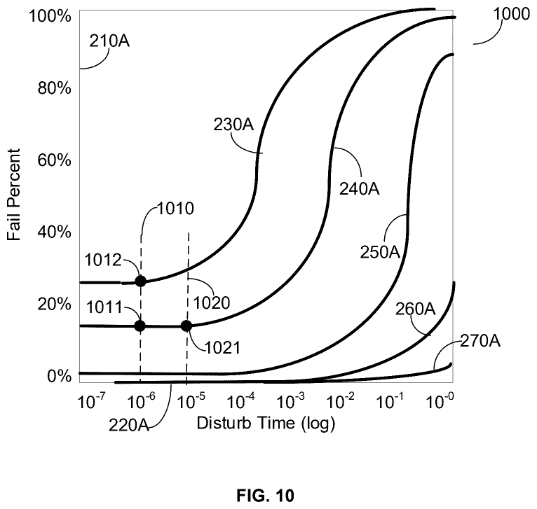

FIG. 10 shows plot 1000 for determination of a desired CLEAN voltage according to an embodiment. The vertical axis 210A denotes the fail percent while the horizontal axis 220A denotes the disturb time on a logarithmic scale. Graphs 230A, 240A, 250A, 260A and 270A, discussed with respect of FIG. 2, represent the read disturb at different V_{read} values, 0.9V, 0.8V, 0.7V, 0.6V and 0.5V respectively. As can be seen in graph 230A some 25% of the ReRAM cells suffer from read disturb at V_{read}=0.9V but this changes after about 1 μSec 1010, crossing graph 230A at 1012 where the number of read disturbed cells begins to increase. At the same time 1010, for a V_{read}=0.8V, where only some 15% of the ReRAM cells exhibit read disturb 1011, the disturb time until ReRAM cells begin being read disturbed again is longer, at about 10 μSec 1020, crossing graph 240A at 1021, where the number of read disturbed cells begins to increase. Hence a tradeoff is shown between the time of read disturb that is longer, but the number of ReRAM cell disturbed is lower. Hence, in the present example it would make sense to select the V_{read} at a value that is between 0.8V and 0.7V to optimize both the number of ReRAM cells that need to be reprogrammed and the time to read disturb that gets longer. Other considerations may be applied without departing from the scope of the invention.

All examples and conditional language recited herein are intended for pedagogical purposes to aid the reader in understanding the principles of the disclosed embodiment and the concepts contributed by the inventor to furthering the art and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A method for initializing a resistive random-access memory (ReRAM) against read disturb, the method comprising:
programming all ReRAM cells of the ReRAM to an initial state at a first programing voltage;
performing a clean operation on all the ReRAM cells, wherein a clean voltage is at a lower absolute value than the first programming voltage, and wherein the clean operation is performed for a predetermined period of time that is longer than a switching time of a first group of ReRAM cells that are read disturbed after a first predetermined number of reads and a second group of ReRAM cells that are read disturbed after a second predetermined number of reads, wherein the first predetermined number of reads is smaller than the second predetermined number of reads; and
performing a read operation on all the ReRAM cells to determine which of the ReRAM cells have been affected by a read disturb, wherein read is performed at an absolute voltage that is lower than the absolute voltage value of the clean operation.

2. The method of claim 1, wherein the initial state is one of low resistive state (LRS) and high resistive state (HRS).

3. The method of claim 2, wherein programming to LRS is a SET operation.

4. The method of claim 2, wherein programming to HRS is a RESET operation.

5. The method of claim 1, further comprising:
performing a reprogramming of those ReRAM cells of the first group of ReRAM cells.

6. The method of claim 5, wherein the reprogramming is performed using at least a reprogramming voltage that is higher in absolute value than the programming voltage.

7. The method of claim 5, wherein the reprogramming is performed using at least a reprogramming current that is higher in absolute value than the programming current.

8. A control logic of a resistive random-access memory (ReRAM) configured to address read disturb of ReRAM cells of the ReRAM, the control logic comprising:
a processing circuitry;
an input/output (IO) interface communicatively connected to the processing circuit, wherein the IO interface comprises at least control signals of the ReRAM; and
a memory communicatively connected to the processing circuitry, the memory containing therein instructions that when executed by the processing circuitry configure the control logic to: program all ReRAM cells of the ReRAM to an initial state at a first programing voltage; perform a clean operation on all the ReRAM cells, wherein a clean voltage is at a lower absolute value than the first programming voltage, and wherein the clean operation is performed for a predetermined period of time that is longer than a switching time of a first group of ReRAM cells that are read disturbed after a first predetermined number of reads and a second group of ReRAM cells that are read disturbed after a second predetermined number of reads, wherein the first predetermined number of reads is smaller than the second predetermined number of reads; and, perform a read operation on all the ReRAM cells to determine which of the ReRAM cells have been affected by a read disturb, wherein read is performed at an absolute voltage that is lower than the absolute voltage value of the clean operation.

9. The control logic of claim 8, wherein the initial state is one of low resistive state (LRS) and high resistive state (HRS).

10. The control logic of claim 9, wherein programming to LRS is a SET operation.

11. The control logic of claim 9, wherein programming to HRS is a RESET operation.

12. The control logic of claim 8, wherein the memory further contains instructions that when executed by the processing circuitry configure the control logic to: perform a reprogram of those ReRAM cells of the first group of ReRAM cells.

13. The control logic of claim 12, wherein the reprogram is performed using at least a reprogramming voltage that is higher in absolute value than the programming voltage.

14. The control logic of claim 12, wherein the reprogram is performed using at least a reprogramming current that is higher in absolute value than the programming current.

15. A resistive random-access memory (ReRAM) configured to address read disturb of ReRAM cells of the ReRAM, the ReRAM comprising:
an array of ReRAM cells;
a word-line decoder communicatively connected to the array of ReRAM cells using at least one word-line;
a bit-line/select-line decoder communicatively connected to the array of ReRAM cells using at least one bit-line and at least one select line;
a control logic communicatively connected to the word-line decoder and to the bit-line/select-line decoder, the control logic comprising: a processing circuitry; an input/output (IO) interface communicatively connected to the processing circuit, wherein the IO interface comprises at least control signals of the ReRAM; and a memory communicatively connected to the processing circuitry, the memory containing therein instructions that when executed by the processing circuitry configure the control logic to: program all ReRAM cells of the ReRAM to an initial state at a first programing voltage; perform a clean operation on all the ReRAM cells, wherein a clean voltage is at a lower absolute value than the first programming voltage, and wherein the clean operation is performed for a predetermined period of time that is longer than a switching time of a first group of ReRAM cells that are read disturbed after a first predetermined number of reads and a second group of ReRAM cells that are read disturbed after a second predetermined number of reads, wherein the first predetermined number of reads is smaller than the second predetermined number of reads; and, perform a read operation on all the ReRAM cells to determine which of the ReRAM cells have been affected by a read disturb, wherein read is performed at an absolute voltage that is lower than the absolute voltage value of the clean operation.

16. The ReRAM claim 15, wherein the initial state is one of low resistive state (LRS) and high resistive state (HRS).

17. The ReRAM of claim 16, wherein programming to LRS is a SET operation.

18. The ReRAM of claim 16, wherein programming to HRS is a RESET operation.

19. The ReRAM of claim 15, wherein the memory further contains instructions that when executed by the processing circuitry configure the control logic to: perform a reprogram of those ReRAM cells of the first group of ReRAM cells.

20. The ReRAM of claim 19, wherein the reprogram is performed using at least a reprogramming voltage that is higher in absolute value than the programming voltage.

21. The ReRAM of claim 19, wherein the reprogram is performed using at least a reprogramming current that is higher in absolute value than the programming current.
